(19) United States
(12) Patent Application Publication
(10) Pub. No.: US 2026/0371820 A1
(43) Pub. Date: Nov. 19, 2026

(54) LED FILAMENT

(71) Applicant: SIGNIFY HOLDING B.V., EINDHOVEN (NL)

(72) Inventors: TIES VAN BOMMEL, HORST (NL); RIFAT ATA MUSTAFA HIKMET, EINDHOVEN (NL)

(21) Appl. No.: 19/150,511

(22) PCT Filed: Jan. 17, 2024
(86) PCT No.: PCT/EP2024/051024

§ 371 Date: Jul. 23, 2025

(30) Foreign Application Priority Data
Jan. 17, 2024 (EP) 23153844.8

(51) Int. Cl. H10H 29/853; F21K 9/232; F21K 9/238; F21V 23/04; F21Y 103/10; F21Y 113/13; F21Y 115/10; H05B 47/155; H05B 47/175; H05B 47/19; H10H 29/851; H10H 29/854

(52) U.S. Cl. CPC H10H 29/853; F21K 9/232; F21K 9/238; F21V 23/0435; H05B 47/155; H05B 47/19; H05B 47/1965; H10H 29/8512; H10H 29/8514; H10H 29/854; F21Y 2103/10; F21Y 2113/13; F21Y 2115/10

(57) ABSTRACT

The present invention relates to an LED filament (10), comprising:—an LED filament (14), comprising:—a carrier (16);—a plurality of first blue LEDs (22) arranged on the carrier and adapted to emit first blue light (24);—a first elongated encapsulant (26) covering the first blue LEDs and at least part of the carrier, wherein the first elongated encapsulant comprises a first luminescent material (28) configured to convert at least part of the first blue light into first converted light (30); and—a top surface (34) on or over the first elongated encapsulant, wherein the LED filament further comprises:—a string (36, 36′) of second blue LEDs (38) arranged on top of the top surface of the LED filament and adapted to emit second blue light (40), wherein light output surfaces (42) of the second blue LEDs are facing away from the LED filament.

### FIELD OF THE INVENTION

The present invention relates to a light-emitting diode (LED) filament. The present invention also relates to a lamp or a luminaire comprising such an LED filament. The present invention also relates to a lighting system comprising such a lamp or luminaire.

### BACKGROUND OF THE INVENTION

A trend in lighting is LED filament lamps. An LED filament lamp is an LED lamp which is designed to resemble a traditional incandescent light bulb with a visible filament for aesthetic and light distribution purposes, but with the high efficiency of light-emitting diodes.

### SUMMARY OF THE INVENTION

It is an object of the present invention to improve performance and/or functionality of LED filaments.

According to a first aspect of the invention, this and other objects are achieved by a light-emitting diode (LED) filament, comprising: a carrier, a plurality of first blue LEDs adapted to emit first blue light, wherein the plurality of first blue LEDs are arranged on the carrier, a first elongated encapsulant covering the plurality of first blue LEDs and at least part of the carrier, wherein the first elongated encapsulant comprises a first luminescent material configured to convert at least part of the first blue light into first converted light, and the first elongated encapsulant having a top surface, wherein the LED filament further comprises a string of second blue LEDs adapted to emit second blue light, wherein the string of second blue LEDs is arranged on top of the top surface of the LED filament, and wherein light output surfaces of the second blue LEDs are facing away from the LED filament.

In this way, optical crosstalk (i.e. the effect that the operated blue LEDs stimulate the phosphor converter of the LED filament which then emits light of a different color) is reduced/not present, such that pure blue colors can be provided.

Preferably less than 5% of the second blue LED light is converted (by the first luminescent material), more preferably less than 3% of the second blue LED light is converted (by the first luminescent material), most preferably less than 1% e.g. 0% of the second blue LED light is converted (by the first luminescent material).

The top surface may have a top surface area (TSA), wherein the string of second blue LEDs has a string area (SA), and wherein SA<0.4TSA, especially SA<0.2TSA. In this way, the string of second blue LEDs the does not block and/or absorb (too much) of the first blue light and/or the first converted light.

The LED filament may further comprise a controller configured to individually control emission of the first blue light by the plurality of first blue LEDs and emission of the second blue light by the string of second blue LEDs. In this way, the LED filament may selectively provide white light, colored light, or combinations thereof.

The string of second blue LEDs may be arranged on a light-transmissive substrate or not arranged on a substrate. By this, the first blue light and/or the first converted light can readily pass the string of second blue LEDs arranged over the first blue LEDs. Although the second blue LEDs and their electrical track(s) may still block some light, first blue light and/or converted light is transmitted through the light-transmissive substrate or just around the second blue LEDs and electrical track(s).

The string of second blue LEDs may be covered by a second elongated encapsulant which is free from a luminescent and light scattering material. In other words, the second elongated encapsulant does not contain any luminescent or light scattering material. In this way, optical LED filament light distribution requirements may be met. The second elongated encapsulant may for example be dome-shaped.

The string of second blue LEDs may have an LED pitch below 1000 μm, preferably below 800 μm, more preferably below 600 μm, and most preferably below 500 μm. The ‘LED pitch’ may be the center-to-center distance between adjacent second blue LEDs of the string.

The LED filament may further comprise a plurality of red LEDs adapted to emit red light and optionally a plurality of green LEDs adapted to emit green light, wherein the plurality of red LEDs and the optional plurality of green LEDs are arranged on the top surface of the LED filament. Alternatively, the plurality of red LEDs and the optional plurality of green LEDs may be arranged on the carrier of the LED filament, for example under or next to the first elongated encapsulant. The plurality of red LEDs and the optional a plurality of green LEDs allow the LED filament to provide light of various colors. Accordingly, the aforementioned controller may further be configured to individually control emission of the red light by the plurality of red LEDs and emission of green light by any plurality of green LEDs.

The plurality of red LEDs and the optional plurality of green LEDs may be arranged in at least one string, such as a string of red LEDs and another string of green LEDs, or a combined string of second blue LEDs, red LEDs and optionally green LEDs. Hence, in one or more embodiments, the string of second blue LEDs only comprises second blue LEDs. And in one or more other embodiments, the string of second blue LEDs also comprises the plurality of red LEDs and the optional plurality of green LEDs.

The first luminescent material may configured to convert at least part of the first blue light into first converted light comprising first green/yellow and first red light forming together with unconverted first blue light emitted by the plurality of first blue LEDs first white light having a first correlated color temperature (CCT1). Preferably, CCT1≤2500K.

The LED filament may further comprise:—a plurality of third blue LEDs adapted to emit third blue light, wherein the plurality of third blue LEDs are arranged on the carrier; and—a third elongated encapsulant covering the plurality of third blue LEDs and part of the carrier, wherein the third elongated encapsulant comprises a second luminescent material configured to convert at least part of the third blue light into second converted light. In this way, LED filament may provide white light with different color temperatures, while still reducing or avoiding optical crosstalk.

The string of second blue LEDs may be arranged at an interface between the first elongated encapsulant and the third elongated encapsulant, to reduce or minimize its influence on the first blue/converted light and the third blue/second converted light.

The second luminescent material may be configured to convert at least part of the third blue light into second converted light comprising second green/yellow and second red light forming together with unconverted third blue light emitted by the plurality of third blue LEDs second white light having a second correlated color temperature (CCT2) higher than the first correlated color temperature. Preferably CCT2-CCT1≥500K, and more preferably CCT2-CCT1≥1000K. Typically CCT2≥3500K. Furthermore, the color rendering index (CRI) of the first white light and the second white light may be at least 80.

According to a second aspect of the invention, there is provided a lamp or luminaire comprising an LED filament according to the first aspect and an antenna functionally coupled to a (the) controller of the LED filament. The antenna allows the lamp or luminaire to be remotely controlled. The lamp could for example be a (retrofit) bulb.

According to a third aspect of the invention, there is provided a lighting system, comprising: a lamp or luminaire according to the second aspect; and at least one (remote) user interface for providing user input and/or at least one (remote) sensor for sensing data, wherein the controller is configured to control the plurality of first blue LEDs, the plurality of second blue LEDs, and optionally the plurality of red LEDs, the plurality of green LEDs, and the plurality of third blue LEDs based on the user input and/or the data.

It is noted that the invention relates to all possible combinations of features recited in the claims.

### BRIEF DESCRIPTION OF THE DRAWINGS

These and other aspects of the present invention will now be described in more detail, with reference to the appended drawings showing embodiments of the invention.

FIG. 1a is a cross-sectional view of an LED filament according to an embodiment of the invention.

FIG. 1b is a side view of the LED filament of FIG. 1a.

FIG. 1c is a top view of the LED filament of FIG. 1a.

FIGS. 2a-e illustrate LED filaments according to other embodiments of the invention.

FIG. 3 is a side view of aspects of the invention including a lamp.

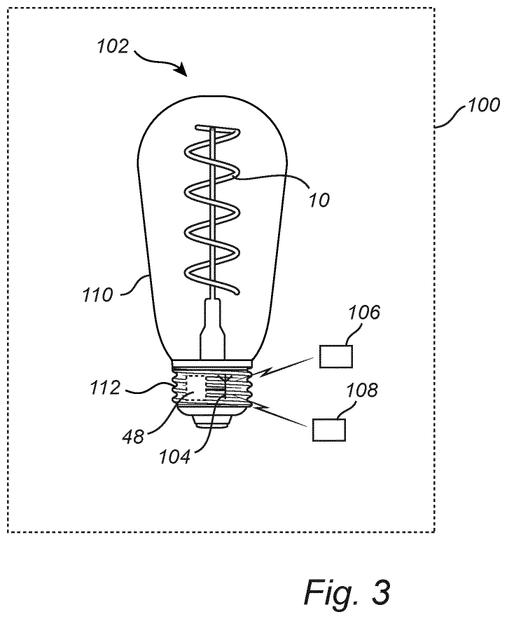

As illustrated in the figures, the sizes of layers and regions may be exaggerated for illustrative purposes and, thus, are provided to illustrate the general structures of embodiments of the present invention. Like reference numerals refer to like elements throughout.

### DETAILED DESCRIPTION

The present invention will now be described more fully hereinafter with reference to the accompanying drawings, in which currently preferred embodiments of the invention are shown. This invention may, however, be embodied in many different forms and should not be construed as limited to the embodiments set forth herein; rather, these embodiments are provided for thoroughness and completeness, and fully convey the scope of the invention to the skilled person.

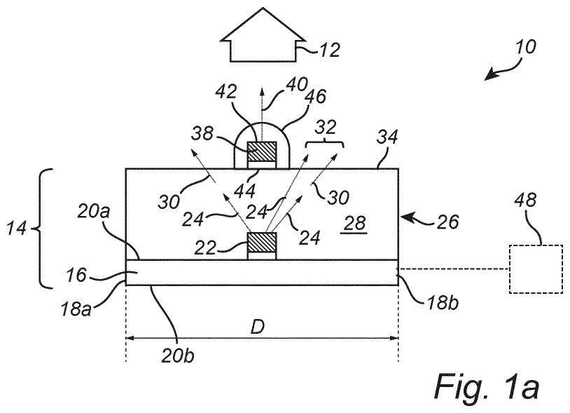

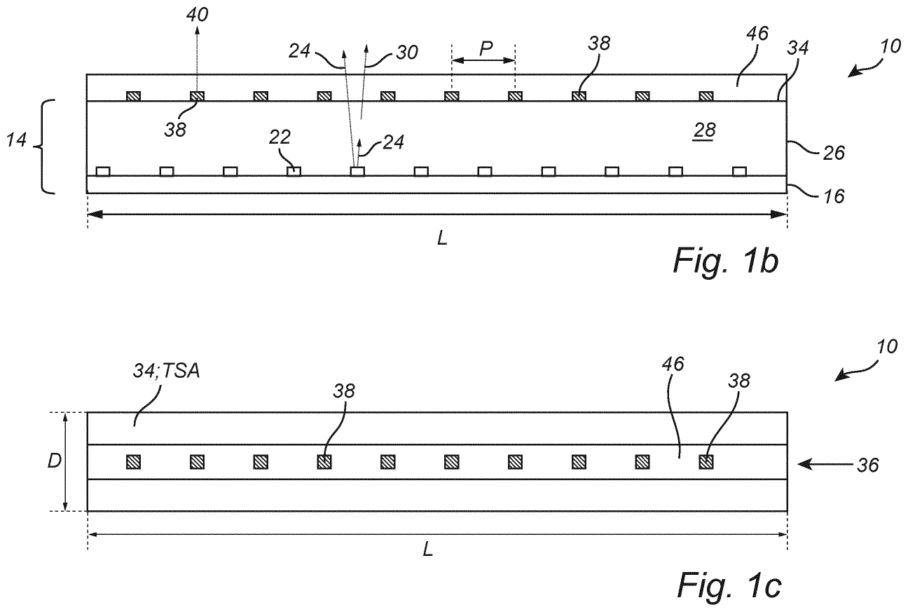

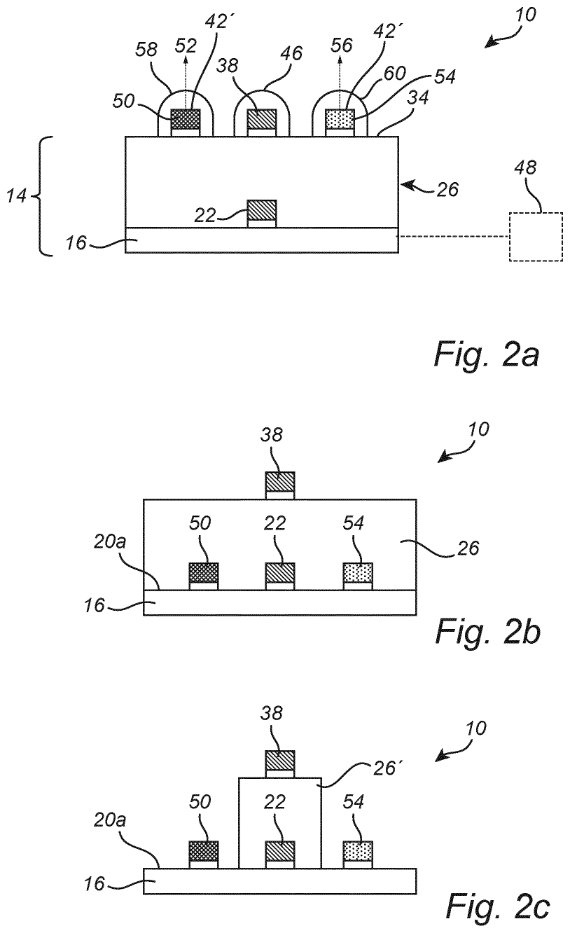

FIGS. 1a-c illustrate an LED filament 10 according to an embodiment of the invention. The LED filament 10 may provide LED filament (arrangement) light 12.

The LED filament 10 comprises an LED filament 14. The LED filament 14 may be rigid or flexible.

The LED filament 14 comprises a carrier 16. The carrier 16 is typically a substrate. The carrier 16 is typically elongated. Preferably, the LED filament 14 has a length L, wherein L>5D. The distance D, which corresponds to the width of the carrier 16, may for example be in a range from 0.5 to 5 mm. The carrier 16 may comprise two elongated edge portions 18a-b arranged at the distance D from each other, a first (major) surface 20a, and a second (major) surface 20b arranged opposite to the first surface 20a. The carrier 16 may be rigid (made from e.g. a polymer, glass, quartz, metal, or sapphire) or flexible (e.g. made of a polymer or metal e.g. a film or foil).

The LED filament 14 further comprises a plurality of first blue LEDs 22 adapted to emit first blue light 24. The first blue light 24 may for example have a dominant peak wavelength in a wavelength range from 450 to 490 nm. The plurality of first blue LEDs 22 are arranged on the carrier 16. Specifically, the plurality of first blue LEDs 22 may be mounted on the first surface 20a of the carrier 16. Furthermore, the plurality of first blue LEDs 22 are preferably arranged in a linear array/string/single column, here on the longitudinal centerline of the carrier 16. The number of first blue LEDs 22 may for example be at least ten or at least twenty first blue LEDs 22.

The LED filament 14 further comprises a first elongated encapsulant 26 covering the plurality of first blue LEDs 22 and at least part of the carrier 16. The first elongated encapsulant 26 comprises a first luminescent material 28 configured to convert at least part of the first blue light 24 into first converted light 30. Specifically, the first luminescent material 28 may be configured to convert at least part of the first blue light 24 into first converted light 30 comprising first green/yellow and first red light forming together with unconverted first blue light 24 first white light 32 having a first correlated color temperature CCT1. Preferably, CCT1≤2500K (warm white light). Furthermore, the color rendering index (CRI) of the first white light 32 is preferably at least 80. The first luminescent material 28 may be a phosphor, and the first elongated encapsulant 26 may otherwise be made of silicone, for example. The plurality of first blue LEDs 22 with the first elongated encapsulant 26 and first luminescent material 28 could be referred to as a first white light source.

The LED filament 14 further comprises a top surface 34, here the top surface 34 of the first elongated encapsulant 26. The top surface 34 is opposite a bottom surface (=second (carrier) surface 20b) of the LED filament 14. The top surface 34 and the bottom surface 20b may be enclosed by edge surfaces. As seen in FIG. 1c, the top surface 34 has a top surface area TSA, typically TSA=L×D.

The LED filament 10 further comprises a second light source comprising a string 36 of second blue LEDs 38 adapted to emit second blue light 40. The string 36 of second blue LEDs 38 here only comprises second blue LEDs 38. The string of second blue LEDs is arranged on top of the top surface 34 of the LED filament 14, either directly or on a light-transmissive substrate (not shown), such that light output surfaces 42 of the second blue LEDs 38 are facing away from the LED filament 14. That is, the second blue light 40 is in operation emitted away from the first encapsulant 26 comprising the luminescent material 28. Each light output surface 42 may be top surface of the blue LED 38, whereas an opposite bottom surface 44 of the blue LED 38 is facing and possibly mounted to (the top surface 34 (of the first elongated encapsulant 26) of) the LED filament 14. As such, the second blue LEDs 38 may be referred to as top emitting second blue LEDs 38. The string of 36 second blue LEDs 38 is preferably arranged at the longitudinal centerline of the top surface 34 of the LED filament 14, as seen in FIG. 1c. That is, the first and second blue LEDs 22, 42 may be arranged in a stack facing the same direction. The number of second blue LEDs 38 may for example be at least ten or at least twenty second blue LEDs 38.

By having the string 36 of second blue LEDs 38 arranged over/in front of the first elongated encapsulant 26/first luminescent material 28 and in operation emitting the second blue LED light 40 away from the same, optical crosstalk (i.e. the effect that the operated blue LEDs 38 would stimulate the phosphor converter/luminescent material 28 of the LED filament which then emits light of a different color) is reduced/not present, such that pure blue colors can be provided.

The string 36 of second blue LEDs 38 may have a string area SA. The string area SA may be the sum of the areas of the light output surfaces 42 of the second blue LEDs 38 and the related electrical track(s). The (approximate) string area SA is indicated with diagonal stripes in FIG. 1c. Preferably SA<0.2TSA, whereby the second blue LEDs 38 the does not block too much of the first blue light 24 and/or the first converted light 30. The electrical track(s) may for example include a copper wire/track. Furthermore, the string 36 of second blue LEDs 36 may have an ultra-low LED pitch P below 1000 μm.

The LED filament 10 may further comprise a second elongated encapsulant 46 covering the string 36 of second blue LEDs 38. The second elongated encapsulant 46 is free from a luminescent material and a light scattering material. The second elongated encapsulant 46 may for example be transparent. The second elongated encapsulant 46 may for example be made of silicone. The second elongated encapsulant 46 may for example have a dome-shaped cross section, with respect to the width D, as seen in fig. la. The dome-shaped cross section may be uniform throughout substantially the complete length of the second elongated encapsulant 46.

The LED filament 10 may further comprise an electronic controller 48. The controller 48 is configured to individually control emission of the first blue light 24 by the plurality of first blue LEDs 22 and emission of the second blue light 40 by the string of second blue LEDs 38. Hence, in operation the LED filament 10 in FIGS. 1a-c may selectively provide white light 32, blue light 40, or combinations thereof.

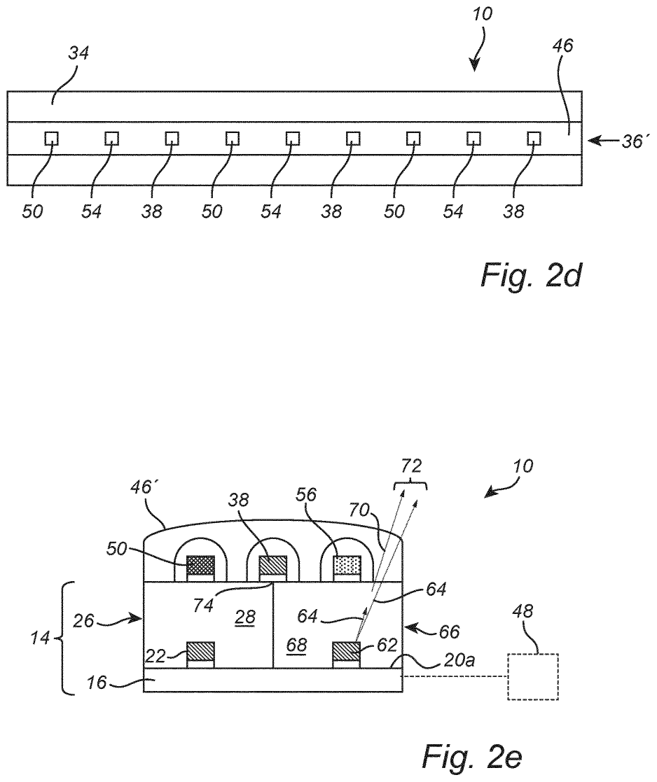

FIG. 2a is a cross-sectional view of an LED filament 10 according to another embodiment. The LED filament 10 in FIG. 2a is similar to that of FIGS. 1a-c, but further comprises a plurality of red LEDs 50 adapted to emit red light 52 and a plurality of green LEDs 54 adapted to emit green light 56. The plurality of red LEDs 50 and the plurality of green LEDs 54 are arranged on the top surface 34 of the LED filament 14, either directly or on a light-transmissive substrate (not shown), such that their light output surfaces 42′ are facing away from the LED filament 14. The plurality of red LEDs 50 are arranged in a string on one side of the string 36 of second blue LEDs 38, wherein the string of red LEDs 50 is parallel to the string 36 of second blue LEDs 38. The plurality of green LEDs 54 are arranged in another string on the other side of the string 36 of second blue LEDs 38, wherein the string of green LEDs 54 also is parallel to the string 36 of second blue LEDs 38. The number of red LEDs 50 may for example be at least ten or at least twenty red LEDs 50. The number of green LEDs 54 may for example be at least ten or at least twenty green LEDs 54. The plurality of red LEDs 50 may be covered by an elongated encapsulant 58 similar to the second elongated encapsulant 46. Likewise, the plurality of green LEDs 54 may be covered by an elongated encapsulant 60 similar to the second elongated encapsulant 46. Alternatively, the second elongated encapsulant 46 could be extended to cover also the red and green LEDs 50, 54 (not shown in FIG. 2a). The controller 48 may here be configured to also individually control emission of the red light 52 by the plurality of red LEDs 50 and emission of green light 56 by any plurality of green LEDs 54. Hence, in operation the LED filament 10 in FIG. 2a may selectively provide white light 32, blue light 40, red light 50, green light 54, or combinations thereof.

FIGS. 2b-c are cross-sectional views of LED filaments 10 according to other embodiments. The LED filament 10 in each of FIGS. 2b-c is similar to that of FIG. 2a, but here the plurality of red LEDs 50 and the plurality of green LEDs 56 are arranged on the carrier 16 of the LED filament 14. Specifically, the plurality of red LEDs 50 may be mounted on the first surface 20a of the carrier 16 (on one side of the plurality of first blue LEDs 22), and the plurality of green LEDs 54 may as well be mounted on the first surface 20a of the carrier 16 (but on the opposite side of the plurality of first blue LEDs 22). Namely, the plurality of red LEDs 50 may be arranged in a string parallel to the linear array/string/single column of first blue LEDs 22. Likewise, the plurality of green LEDs 54 may be arranged in another string parallel to the linear array/string/single column of first blue LEDs 22.

In FIG. 2b the first elongated encapsulant 26 covers the plurality of first blue LEDs 22 as well as the plurality of red LEDs 50 and the plurality of green LEDs 54 and at least part of the carrier 16. In FIG. 2c the first elongated encapsulant designated by reference sign 26′ has a limited extension in the width direction and (only) covers the plurality of first blue LEDs 22 and part of the carrier 16, but not the plurality of red LEDs 50 and the plurality of green LEDs 54. The plurality of red LEDs 50 and the plurality of green LEDs 54 may be uncovered, or be provided with elongated encapsulants 58, 60 similar to FIG. 2a (not shown in FIG. 2c).

FIG. 2d is a top view of an LED filament 10 according to another embodiment. The LED filament 10 in FIG. 2d is similar to that of FIG. 2a, but here the string with the second blue LEDs 38 also comprises the plurality of red LEDs 50 and the plurality of green LEDs 54. That is, the plurality of second blue LEDs 38, the plurality of red LEDs 50, and the plurality of green LEDs 54 are arranged in a single string/linear/column 36′, preferably at the longitudinal centerline of the top surface 34 of the LED filament 14. The LEDs 38, 50, 54 may be arranged in alternating order of color (e.g. R-G-B-R-G-B and so on, i.e. (RGB)n with n preferably ≥5) in the string 36′, although other arrangements such as batching could be possible as well. Here, the second elongated encapsulant 46 may cover also the red and green LEDs 50, 54.

FIG. 2e is a cross-sectional view of an LED filament 10 according to another embodiment. The LED filament 10 in FIG. 2e is similar to that of FIG. 2a, but here the LED filament 14 further comprises a plurality of third blue LEDs 62 adapted to emit third blue light 64. The plurality of third blue LEDs 62 are arranged on the carrier 16. Specifically, the plurality of third blue LEDs 62 may be mounted on the first surface 20a of the carrier 16. Furthermore, the plurality of third blue LEDs 62 are preferably arranged in a linear array/string/single column. The string of third blue LEDs 62 may the arranged parallel to the aforementioned string of first blue LEDs 22. These strings may be mounted on either side of the longitudinal centerline of the carrier 16, as shown in FIG. 2e. The number of third blue LEDs 62 may for example be at least ten or at least twenty third blue LEDs 62.

The LED filament 14 in FIG. 2e further comprises a third elongated encapsulant 66 covering the plurality of third blue LEDs and part of the carrier 16. The third elongated encapsulant 66 comprises a second luminescent material 68 configured to convert at least part of the third blue light 64 into second converted light 70. Specifically, the second luminescent material 68 may be configured to convert at least part of the third blue light 64 into second converted light 70 comprising second green/yellow and second red light forming together with unconverted third blue light 64 second white light 72 having a second correlated color temperature CCT2, wherein the second correlated color temperature CCT2 is different than the first correlated color temperature CCT1. Preferably CCT2-CCT1>500K, and more preferably CCT2-CCT1≥1000K. Typically CCT2≥3500K. Furthermore, the color rendering index (CRI) of the second white light 72 is preferably at least 80. The second luminescent material 68 may be a phosphor, and the second elongated encapsulant 66 may otherwise be made of silicone, for example. The plurality of third blue LEDs 62 with the third elongated encapsulant 66 and second luminescent material 68 could be referred to as a third white light source.

Each of the first and third elongated encapsulants 26 and 66 may cover approximately half of the carrier 16, as seen in the width direction. As such, the first and third elongated encapsulants 26 and 66 may be parallel to each other (in the length direction of the LED filament 12/LED filament 14). And the top surface 34 of the LED filament 14 may here be formed by the top surfaces of the first and third elongated encapsulants 26 and 66. Furthermore, the string of second blue LEDs 38 may be arranged at the interface 74 (at the top surface 34) between the first elongated encapsulant 26 and the third elongated encapsulant 66. The plurality of red LEDs 50 may be arranged on the first elongated encapsulant 26, and the plurality of green LEDs 54 may be arranged on the third elongated encapsulant 66. Alternatively, a single string of the second blue LEDs 38, the red LEDs 50, and the green LEDs 54 (as in FIG. 2d) could be arranged at the interface 74 (not shown).

The controller 48 may here be configured to also individually control emission of the third blue light 64 by the plurality of third blue LEDs 62. Hence, in operation the LED filament 10 in FIG. 2e may selectively provide first white light 32, second white light 72, blue light 40, red light 50, green light 54, or combinations thereof. Furthermore, the second elongated encapsulant could here be a common elongated encapsulant 46′ covering the string 36 of second blue LEDs 38 as well as the plurality of red LEDs 50 and any plurality of green LEDs 54. The common elongated encapsulant 46′ could simplify manufacturing of the LED filament 10. Alternatively, the LED filament 10 in FIG. 2e could have individual elongated encapsulants 46, 58, 60 as in FIG. 2a, for example.

FIG. 4 illustrates a lamp 102 according to an aspect of the invention. The lamp 102 comprises at least one LED filament 10, the controller 48, and an antenna 104 functionally coupled to the controller 48. The antenna 104 may be configured to receive user input from at least one user interface 106 and/or data from at least one sensor 108. And the controller 54 may be configured to control the plurality of first blue LEDs 22, the plurality of second blue LEDs 38, and any red LEDs 50, green LEDs 54, and third blue LEDs 62 based on the user input from the user interface 106 and/or (sensed) data from the at least one sensor 108. The lamp 102 and the user interface 106 and/or the sensor(s) 108 may be referred to as a lighting system 100. The user interface 106 and/or the sensor(s) 108 may be remote of the lamp 102. The user interface 106 may for example be embodied on a mobile phone. The at least one sensor 108 may for example include at least one of: a camera, a light sensor, a presence sensor, and a proximity sensor.

The LED filament 14/LED filament 10 is here arranged in a coiled configuration, but other configurations such as a straight configuration are possible as well. The lamp 102 may further comprise an envelope 110 enclosing the LED filament 14/LED filament 10, and a cap or base 112 for electrically and mechanically connecting the lamp 102 to an external socket (not shown). The lamp 102 may for example be a retrofit bulb.

The person skilled in the art realizes that the present invention by no means is limited to the preferred embodiments described above. On the contrary, many modifications and variations are possible within the scope of the appended claims.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

1. A light-emitting diode, LED, filament, comprising:
a carrier;
a plurality of first blue LEDs adapted to emit first blue light, wherein the plurality of first blue LEDs are arranged on the carrier;
a first elongated encapsulant covering the plurality of first blue LEDs and at least part of the carrier, wherein the first elongated encapsulant comprises a first luminescent material configured to convert at least part of the first blue light into first converted light; the first elongated encapsulant having a top surface, and
a string of second blue LEDs adapted to emit second blue light, wherein the string of second blue LEDs is directly mounted on the top surface of the first elongated encapsulant, and wherein light output surfaces of the second blue LEDs are facing away from the top surface.

2. The LED filament according to claim 1, wherein the top surface has a top surface area, TSA, wherein the string of second blue LEDs has a string area, SA, and wherein SA<0.4TSA.

3. The LED filament according to claim 1, further comprising a controller configured to individually control emission of the first blue light by the plurality of first blue LEDs and emission of the second blue light by the string of second blue LEDs.

4. The LED filament according to claim 1, wherein the string of second blue LEDs is arranged on top of the top surface of the first elongated encapsulant (26), either directly or on a light-transmissive substrate.

5. The LED filament according to claim 1, wherein the string of second blue LEDs is covered by a second elongated encapsulant which is free from a luminescent and light scattering material.

6. The LED filament according to claim 1, wherein the string of second blue LEDs has an LED pitch below 1000 μm.

7. The LED filament according to claim 1, further comprising a plurality of red LEDs adapted to emit red light and optionally a plurality of green LEDs adapted to emit green light, wherein the plurality of red LEDs and the optional plurality of green LEDs are arranged on the top surface of the first elongated encapsulant.

8. The LED filament according to claim 7, wherein the plurality of red LEDs and the optional plurality of green LEDs are arranged in at least one string.

9. The LED filament according to claim 7, wherein the string of second blue LEDs only comprises second blue LEDs.

10. The LED filament according to claim 7, wherein the string of second blue LEDs also comprises the plurality of red LEDs and the optional plurality of green LEDs.

11. The LED filament according to claim 1, wherein the first luminescent material is configured to convert at least part of the first blue light into first converted light comprising first green/yellow and first red light forming together with unconverted first blue light emitted by the plurality of first blue LEDs first white light having a first correlated color temperature, CCT1, wherein CCT1≤2500K.

12. The LED filament according to claim 1, wherein the LED filament further comprises:
a plurality of third blue LEDs adapted to emit third blue light, wherein the plurality of third blue LEDs are arranged on the carrier; and
a third elongated encapsulant covering the plurality of third blue LEDs and part of the carrier, wherein the third elongated encapsulant comprises a second luminescent material configured to convert at least part of the third blue light into second converted light.

13. The LED filament according to claim 12, wherein the string of second blue LEDs is arranged at an interface between the first elongated encapsulant and the third elongated encapsulant.

14. The LED filament according to claim 11, wherein the second luminescent material is configured to convert at least part of the third blue light into second converted light comprising second green/yellow and second red light forming together with unconverted third blue light emitted by the plurality of third blue LEDs second white light having a second correlated color temperature, CCT2, higher than the first correlated color temperature, wherein CCT2-CCT1>500K, and wherein the color rendering index, CRI, of the first white light and the second white light is at least 80.

15. A lighting system, comprising:
a lamp or luminaire comprising an LED filament according to claim 1 and an antenna functionally coupled to a controller of the LED filament; and
at least one user interface for providing user input and/or at least one sensor for sensing data,
wherein the controller is configured to control the plurality of first blue LEDs, the plurality of second blue LEDs, and optionally the plurality of red LEDs, the plurality of green LEDs, and the plurality of third blue LEDs based on the user input and/or the data.
